(19) United States
(12) Patent Application Publication
(10) Pub. No.: US 2004/0036066 A1
(43) Pub. Date: Feb. 26, 2004

(54) Ionising radiation detector comprising polymer semiconductor material

(76) Inventors: William Eccleston, Merseyside (GB); Philip Patrick Allport, Wirral (GB); Nigel Anthony Smith, Lancs (GB); Gianluigi Casse, Liverpool (GB)

Correspondence Address: Stephen M DeKlerk, Blakely Sokoloff Taylor & Zafman, Seventh Floor, 12400 Wilshire Boulevard, Los Angeles, CA, 90025-1030, US

(21) Appl. No.: 10/297,283

(22) PCT Filed: Jun. 4, 2001
(86) PCT No.: PCT/GB01/02457

(30) Foreign Application Priority Data
Jun. 3, 2000 (GB) 0013472.6

(51) Int. Cl. H01L 31/075

(52) U.S. Cl. 257/40; 257/458

(57) ABSTRACT

An ionising radiation detector is disclosed which utilises a detector body (16) comprising polymer or oligomer semiconductor material. Means are provided for detecting electron/hole pairs formed in the detector body by ionising radiation and may comprise a pair of electrodes (4, 8) separated by the detector body.

The present invention is concerned with radiation detectors.

Ionising radiation is detected through the energy it deposits in matter. Thus for example in the medical field X-rays may be detected due to the chemical changes their energy causes in a photographic plate.

The favoured method of detecting ionising radiation in certain contexts, however, involves the use of a single crystal inorganic semiconductor such as silicon. Ionising radiation incident upon this material produces electron/hole pairs which can be electronically recorded. Detector area is paramount in the clinical field. It must match the scale of the human body. Large area detectors on single crystal silicon are very expensive to produce.

The range of radiation wavelengths which can be detected using inorganic semiconductor based detectors is limited. If a photon of the incident radiation is to be absorbed in creation of an electron/hole pair (e/h), its energy must correspond to that required to promote an electron from the valence to the conduction band. Photons having insufficient radiation to promote an electron are less likely to create the e/h pair and so be detected. Excessively energetic electrons are also less likely to create the required pair and to be detected. Hence the range of photon energies, and wavelengths, which can be detected are dependent on the band structure (including particularly the band gap) of the detector material. Silicon and other suitable inorganic semiconductors have a limited range of band gaps.

An object of the present invention is to overcome one or more of the shortcomings of the known radiation detectors referred to above.

In particular it is desired to make possible large area radiation detectors. These are preferably to be more straightforward and/or economical in manufacture than silicon based detectors.

It is also desired to make possible production of detectors for radiation of wavelengths which cannot be detected using silicon based detectors.

In accordance with the present invention there is an ionising radiation detector comprising a detector body comprising polymer semiconductor material or oligomer semiconductor material, the material in either case being such that passage of ionising radiation of a selected type produces electron/hole pairs, a first electrode forming with the detector body a first Schottky diode biased against electron injection to the body, a second electrode forming with the detector body a second Schottky diode biased against hole injection to the body, the first and second electrodes being separated by the detector body, means for applying a biasing voltage across the electrodes and means for detecting a signal across the electrodes formed due to the formation of electron/hole pairs in the detector body by ionising radiation.

It is desirable that electrons and holes should move a long way through the body with minimal recombination. The two Schottky diodes of the present invention suppress the availability of electrons and holes for such recombination in the body.

Polymer/oligomer semiconductor materials offer numerous advantages over the inorganic rial used in known detectors Conjugated polymers and oligomers are ideally suited to large area devices. They can be cast or spun from a solvent, or they can be evaporated over large areas to produce thin films on a wide range of substrate materials. Alternatively the materials can be moulded from solution. The substrate can be planar or shaped to suit a particular application. The range of materials available is very large as is the range of energy gaps. There is an increasing number of polymers available which can be dissolved in solvents, making processing simple and low cost.

It is particularly preferred that the polymer or oligomer material is conjugated.

To increase the probability of detection of e/h pairs, relatively high carrier mobilities with relatively long carrier lifetimes and low trapping are desirable. These properties can be achieved using the polymers/oligomers and in particular using regioregular polythiophenes (polyalkylthiophenes in particular being known to be suitable). These materials are available with high degrees of perfection and consequent high mobility.

The detector body may be formed as a film upon a substrate.

The means for detecting the electron hole pairs preferably comprise a pair of electrodes separated by the detector body.

A specific embodiment of the present invention will now be described, by way of example only, with reference to the accompanying drawings in which:—

FIG. 1 illustrates in schematic side view the structure of a detector embodying the present invention;

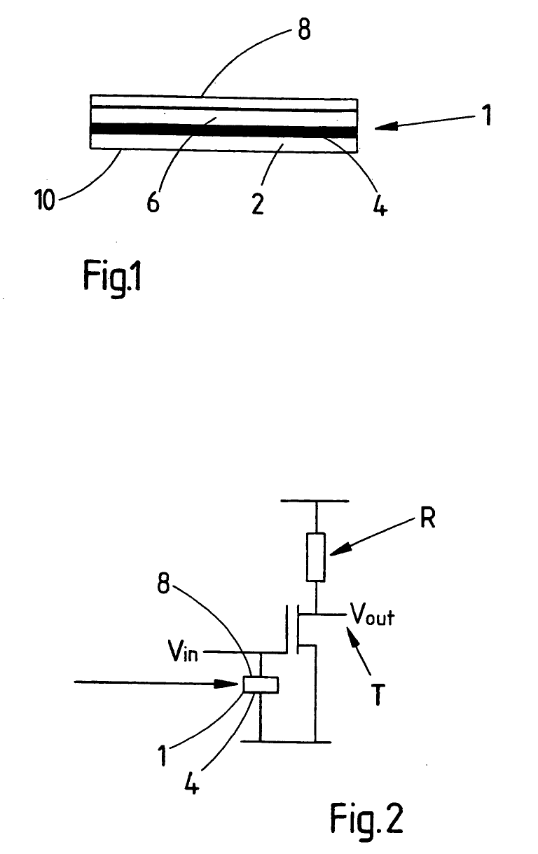

FIG. 2 is a diagram of a circuit incorporating the detector; and

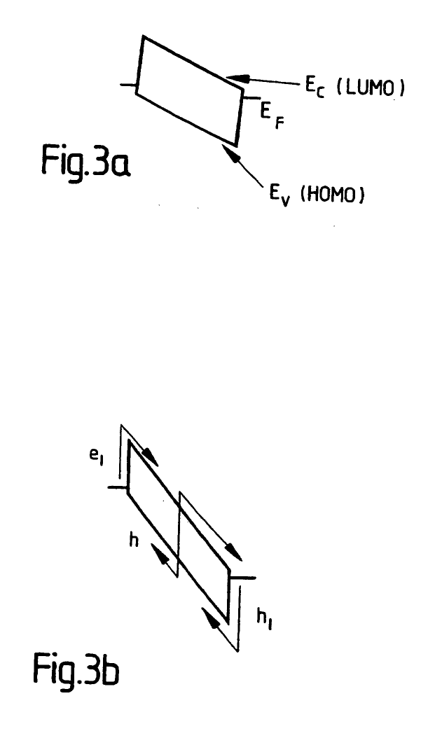

FIGS. 3a and 3b are energy level diagrams illustrating the band structure in the body of the detector with and without applied electrical bias, respectively.

The detector 1 illustrated in FIG. 1 comprises a substrate 2 upon which is a lower electrode 4 while upon the electrode 4 is detector body 6 itself On the upper surface of the detector body 6 is an upper electrode 8. This is illustrated only schematically. A pixellated set of electrodes may in practice be provided In the illustration the structure is formed in an optional tray 10.

The operation of the detector will now be explained, with reference to FIGS. 2 and 3, before going on to consider the detail of its construction.

In FIG. 2 it can be seen that the upper and lower electrodes 4, 8 of the detector are connected across a bias voltage Vᵢₙ. The effect of the bias voltage on the band structure of the detector body 6 can be appreciated by comparing FIGS. 3a and 3b. In both, the left hand edge of the diagram corresponds to the negatively biased side of the detector body 6 and the right hand edge corresponds to its positively biased side. In conventional manner the Fermi level, lying within the band gap, is labelled E_{F} while the upper edge of the valence band and the lower edge of the conduction band are respectively labelled Eᵥ and E_{c} (in chemist's terminology these band edges are respectively referred to as “HOMO” and “LUMO”)

The Fermi level E_{F} has an energy well below the conduction band, so significant electron injection is very improbable in the absence of ionising radiation. Similarly, significant hole injection is improbable at the positive end of the detector because the Fermi level is well above the valence band. Hence despite the applied bias voltage, little or no current flows across the detector.

However when ionising radiation having energy ε₁ is absorbed to promote an electron to the conduction band, creating a corresponding hole in the valence band, these charge carriers move under the influence of the biasing field, as shown by arrows in FIG. 3b. The carriers drift through the material towards the metal inducing increasing amounts of opposite charge in the two electrodes. The rate of arrival of charge on the two electrodes is the current which, when detected in the external circuit, indicates the presence of the ionising radiation.

The current is electronically detected—in FIG. 2 a transistor T and associated load resistor R are used. The circuit will be considered in more detail below.

Looking now in more detail at the detector body 6 itself, this comprises an organic polymer or oligomer material. Whereas in the inorganic materials used in known detectors an electron and hole created by ionising radiation are not bound together, in the organic materials used in the present invention the electron and hole would typically be bound as excitons. Separation of the electron and hole (so that they can contribute to the detected current) may be facilitated by admixture in the detector body 6 of a second material. This second material can be mixed in at the solvent stage of manufacture. One suitable material is Buckminsterfullerene (C60).

The detector body 6 needs to be thick enough to give an acceptable probability that a photon of incident radiation will create an electron hole pair. The currently favoured polymer film is a regioregular polyalkylthiophene with a head to tail count approaching 100%. It may be formed as a film by casting or dip coating upon the coated substrate. In order to minimise voids in the film these procedures are carried out in an atmosphere of the solvent, typically chloroform. Controlled drying is required, particularly with thick films. For some types of radiation the film is required to be very thick—of the order of 1 mm—and moulding of such films is facilitated by the optional tray 10, in which the coated substrate is placed.

Where the detector body 6 is formed as an oligomer film, similar considerations apply but the material is typically evaporated (at much lower temperature than is common with metals). Soluble versions of oligomer materials are being developed at several laboratories so that in future solution based techniques will be usable with these materials as well.

It is desirable that the charge carriers—electrons and holes—should move a large distance through the material with minimal recombination Much depends on the availability of the opposite carrier and this can be suppressed by the use of appropriate Schottky barriers at the junctions between the detector body 6 and the electrodes 4, 8. Hence the electrode and body materials are typically chosen such that these junctions serve as Schottky diodes.

The lower electrode 4 is, in the illustrated embodiment, a metal film formed on the substrate by thermal evaporation, although in re versions the metal may be replaced with a very conductive polymer. The metal of the lower electrode may be gold, in which case aluminum or calcium may be used for the upper electrode.

One or both of the electrodes should be at least substantially transparent to the radiation to be detected. The upper electrode can be pixellated, with bonded wires to carry signals from individual pixels. Bonding of wires is relatively straightforward with aluminum upper electrodes but more problematic using calcium To overcome such difficulties calcium could be used as the lower electrode 4 with a gold upper electrode 8—wire bonds to a gold film can be made provided adhesion of the gold is good, which can be assisted by chromium in the film Calcium has a high Fermi level—very near to Ec—so that it is a very poor hole injector and in this respect is preferable to aluminum.

Other suitable materials for the electrodes include silver and Indium/Tin Oxide (ITO). ITO is conductive but transparent.

The substrate 2 can be of glass or plastics.

Looking again at the detector circuit illustrated in FIG. 2, in operation a negative gate pulse is applied to the gate of the p channel transistor T which stores the charge so that the output voltage of the circuit rises to a voltage of V_{DD}. The charge leaks through the detector when there is incident radiation. The gate is discharged and Vₒᵤₜ falls to near the ground voltage. The presence of a negative going output spike indicates that radiation has been incident on the detector. The load is likely to be a second p channel transistor.

There has been a considerable amount of work on sophisticated techniques of signal processing for detection of ionising radiation. Suitable circuits for processing the signals, which may be short lived, are therefore known and will not be described in more detail here.

It is possible to incorporate the illustrated transistor T, and also the second transistor referred to above, in the detector itself. This can be achieved by forming both or either as a thin film transistor having a semiconductor body of polymer or oligomer material, which may be the same material used for the detector body.

1. An ionising radiation detector comprising a detector body comprising polymer semiconductor material or oligomer semiconductor material, the material in either case being such that passage of ionising radiation of a selected type produces electron/hole pairs, a first electrode forming with the detector body a first Schottky diode biased against electron injection to the body, a second electrode forming with the detector body a second Schottky diode biased against hole injection to the body, the first and second electrodes being separated by the detector body, means for applying a biasing voltage across the electrodes and means for detecting a signal across the electrodes formed due to the formation of electron/hole pairs in the detector body by ionising radiation.

2. An ionising radiation detector as claimed in claim 1 wherein the detector body is a regioregular polythiophene.

3. An ionising radiation detector as claimed in claim 1 or claim 2 wherein the detector body is a polyalkylthiophene.

4. An ionising radiation detector as claimed in claim 3 wherein the polyalkylthiophene is regioregular.

5. An ionising radiation detector as claimed in any preceding claim wherein the detector body comprises an admix e of a second material which facilitates separation of electron/hole pairs.

6. An ionising radiation detector as claimed in any preceding claim wherein the detector body comprises an admixture of Buckminsterfullerene.

7. An ionising radiation detector as claimed in any preceding claim wherein the detector body comprises a film upon a substrate.

8. An ionising radiation detector as claimed in claim 7 wherein at least one of the electrodes is formed as a film at a face of the detector body.

9. An ionising radiation detector as claimed in claim 8 wherein the at least one electrode is at least substantially transparent to the radiation to be detected.

10. An ionising radiation detector as claimed in any preceding claim wherein at least one of the electrodes is pixellated.

11. An ionising radiation detector as claimed in claim 10 wherein bonded wires are provided to carry signals from individual pixels.

12. An ionising radiation detector as claimed in any preceding claim wherein one of the electrodes comprises gold and the other comprises aluminum or calcium.

13. An ionising radiation detector substantially as herein described with reference to and as schematically illustrated in the accompanying drawings.
